(19) United States
(12) Patent Application Publication
(10) Pub. No.: US 2023/0178344 A1
(43) Pub. Date: Jun. 8, 2023

(54) EVAPORATIVE COOLING OF ELECTROSTATIC CHUCKS

(71) Applicant: LAM RESEARCH CORPORATION, Fremont, CA (US)

(72) Inventors: John DREWERY, San Jose, CA (US); Kevin FLYNN, Novato, CA (US); Jeremy George SMITH, Oakland, CA (US); Tom A. KAMP, San Jose, CA (US)

(21) Appl. No.: 17/924,618

(22) PCT Filed: May 4, 2021
(86) PCT No.: PCT/US2021/030558

§ 371 Date: Nov. 10, 2022

Related U.S. Application Data
(60) Provisional application No. 63/025,043, filed on May 14, 2020.

(51) Int. Cl. H01J 37/32

(52) U.S. Cl. CPC H01J 37/32724; H01J 37/32449; H01J 2237/002; H01J 2237/334; H01J 2237/3321

(57) ABSTRACT

A baseplate of a substrate support assembly includes a cavity between an upper region, a lower region, and sidewalls of the baseplate, a plurality of pillars arranged in the cavity between the upper and lower regions, an inlet to supply a liquid to the cavity, and an outlet to vent vapor of the liquid. In another implementation, a baseplate of a substrate support assembly includes a first channel arranged in the baseplate, a second channel arranged above the first channel, a plurality of vertical channels connecting the first channel to the second channel, an inlet to supply a liquid to the first channel, and an outlet to vent vapor of the liquid from the second channel.

### CROSS-REFERENCE TO RELATED APPLICATIONS

This application claims the benefit of U.S. Provisional Application No. 63/025,043, filed on May 14, 2020. The entire disclosure of the application referenced above is incorporated herein by reference.

### FIELD

The present disclosure relates generally to substrate processing systems and more particularly to evaporative cooling of electrostatic chucks used in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, plasma enhanced chemical vapor deposition (PECVD), chemically enhanced plasma vapor deposition (CEPVD), sputtering physical vapor deposition (PVD), atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support assembly such as a pedestal or an electrostatic chuck (ESC) arranged in a processing chamber of the substrate processing system. A robot typically transfers substrates from one processing chamber to another in a sequence in which the substrates are to be processed. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. The processing chambers are periodically cleaned by supplying a cleaning gas into the processing chamber and striking plasma.

### SUMMARY

A baseplate of a substrate support assembly comprises a cavity between an upper region, a lower region, and sidewalls of the baseplate, a plurality of pillars arranged in the cavity between the upper and lower regions, an inlet to supply a liquid to the cavity, and an outlet to vent vapor of the liquid.

In another feature, the pillars are coated with a wicking material.

In another feature, the cavity is cylindrical and a height of the cavity is less than a diameter of the cavity.

In another feature, the pillars are cylindrical and extend from a bottom of the cavity to a top of the cavity.

In another feature, the pillars are cylindrical and extend vertically from a bottom of the cavity to a top of the cavity.

In another feature, the baseplate and the cavity are cylindrical, and the cavity extends radially along a diameter of the baseplate.

In another feature, the inlet is smaller in size than the outlet.

In another feature, the inlet is adjacent to a bottom of the cavity, and the outlet is adjacent to a top of the cavity.

In another feature, the baseplate further comprises a channel arranged in the baseplate above the cavity. The outlet is connected to a first end of the channel. A second end of the channel is connected to a vent in the baseplate.

In other features, the baseplate and the cavity are cylindrical, the channel is spiral shaped, and the cavity and the channel extend radially along a diameter of the baseplate.

In other features, the baseplate and the cavity are cylindrical, the channel is bifilar, and the cavity and the channel extend radially along a diameter of the baseplate.

In another feature, a second cavity between the cavity and the lower region of the baseplate. The outlet is connected to the second cavity. The second cavity is connected to a vent in the baseplate.

In other features, a channel arranged in the baseplate above the cavity, and a second cavity between the cavity and the lower region of the baseplate. The outlet is connected to a first end of the channel and to the second cavity. The second cavity and a second end of the channel are connected to respective vents in the baseplate.

In another feature, the channel is bifilar or spiral shaped.

In another feature, the baseplate is cylindrical; and the cavity, the channel, and the second cavity extend radially across a diameter of the baseplate.

In still other features, a baseplate of a substrate support assembly comprises a first channel arranged in the baseplate, a second channel arranged above the first channel, a plurality of vertical channels connecting the first channel to the second channel, an inlet to supply a liquid to the first channel, and an outlet to vent vapor of the liquid from the second channel.

In another feature, the second channel has a larger cross-section than the first channel.

In another feature, inner walls of the second channel are coated with a wicking material.

In another feature, the first and second channels are spiral shaped.

In another feature, the first and second channels are bifilar.

In another feature, the first and second channels are parallel to each other.

In another feature, the baseplate is cylindrical, and the first and second channels extend radially across a diameter of the baseplate.

In another feature, the inlet is connected to a first end of the first channel, a second end of the first channel is terminated, a first end of the second channel is terminated, and a second end of the second channel is connected to the outlet.

In other features, the inlet is connected to a first end of the first channel, and a second end of the first channel is terminated. The baseplate further comprises a third channel arranged above the second channel. A first end of the second channel is connected to a first end of the third channel. A second end of second channel is terminated. A second end of the third channel is connected to the outlet.

In other features, the second channel has a larger cross-section than the first channel, and the third channel has a larger cross-section than the second channel.

In another feature, the third channel is bifilar or spiral shaped and is parallel to the first and second channels.

In other features, the first, second, and third channels are spiral shaped; and the third channel spirals in an opposite direction relative to the first and second channels.

In other features, the baseplate is cylindrical; and the first, second, and third channels extend radially across a diameter of the baseplate.

In other features, the inlet is connected to a first end of the first channel, and a second end of the first channel is terminated. The baseplate further comprises a cavity between the first channel and a bottom region of the baseplate. A first end of the second channel is connected to the cavity. A second end of second channel is terminated. The cavity is connected to the outlet.

In other features, the baseplate is cylindrical, and the first and second channels and the cavity extend radially across a diameter of the baseplate.

In other features, the baseplate further comprises a plurality of porous plugs. Each of the porous plugs has a first end connected to the first channel and a second end connected to a passage connecting the first end of the second channel to the cavity.

In other features, the vertical channels connecting the first channel to the second channel extend below the first ends of the porous plugs towards a center of the first channel.

In other features, the inlet is connected to a first end of the first channel, and a second end of the first channel is terminated. The baseplate further comprises a third channel arranged above the second channel, and a cavity between the first channel and a bottom region of the baseplate. A first end of the second channel is connected to a first end of the third channel and to the cavity. A second end of second channel is terminated. A second end of the third channel and the cavity are connected to respective vents in the baseplate.

In other features, the second channel has a larger cross-section than the first channel, and the third channel has a larger cross-section than the second channel.

In another feature, the third channel is bifilar or spiral shaped and is parallel to the first and second channels.

In other features, the first, second, and third channels are spiral shaped; and the third channel spirals in an opposite direction relative to the first and second channels.

In other features, the baseplate is cylindrical; and the first, second, and third channels and the cavity extend radially across a diameter of the baseplate.

In other features, the baseplate further comprises a refrigeration system, a level sensor, and a controller. The refrigeration system is configured to supply the liquid to the inlet based on feedback from the outlet. The level sensor is disposed in the first channel to sense a level of the liquid in the first channel. The controller is configured to control supply of the liquid from the refrigeration system to the inlet based on the level of the liquid in the evaporative cooling system.

In still other features, a substrate processing system comprises a substrate support assembly, an evaporative cooling system disposed in the substrate support assembly, a liquid supply configured to provide liquid to the evaporative cooling system, a level sensor disposed in the evaporative cooling system to sense a level of the liquid in the evaporative cooling system, and a controller configured to control supply of the liquid from the liquid supply to the evaporative cooling system based on the level of the liquid in the evaporative cooling system.

In other features, the substrate processing system further comprises a gas supply to provide a pressurized gas to the liquid supply, and a pressure sensor to sense a system pressure in the substrate support assembly. The controller is configured to control supply of the pressurized gas from the gas supply to the liquid supply based on the system pressure, and to control a pressure at which the liquid evaporates based on the controlled supply of the pressurized gas from the gas supply to the liquid supply.

In other features, the evaporative cooling system comprises a cavity between an upper region, a lower region, and sidewalls of the substrate support assembly and a plurality of pillars arranged in the cavity between the upper and lower regions. The pillars are coated with a wicking material. The evaporative cooling system comprises an inlet to supply the liquid from the liquid supply to the cavity, and an outlet to vent vapor of the liquid.

In another feature, the evaporative cooling system comprises a channel arranged in the substrate support assembly above the cavity. The outlet is connected to the channel. The channel is connected to a vent in the substrate support assembly.

In another feature, the evaporative cooling system comprises a second cavity in the substrate support assembly between the cavity and the lower region of the substrate support assembly. The outlet is connected to the second cavity. The second cavity is connected to a vent in the substrate support assembly.

In other features, the evaporative cooling system comprises a channel arranged in the substrate support assembly above the cavity, and a second cavity in the substrate support assembly between the cavity and the lower region of the substrate support assembly. The outlet is connected to the channel and to the second cavity. The second cavity and the channel are connected to respective vents in the substrate support assembly.

In other features, the evaporative cooling system comprises a first channel arranged in the substrate support assembly, a second channel arranged in the substrate support assembly above the first channel and a plurality of vertical channels arranged in the substrate support assembly to connect the first channel to the second channel. The evaporative cooling system comprises an inlet to supply the liquid from the liquid supply to the first channel, and an outlet to vent vapor of the liquid from the second channel.

In another feature, the evaporative cooling system comprises a third channel arranged in the substrate support assembly above the second channel. The third channel is connected to the second channel and to the outlet. The second channel has a larger cross-section than the first channel. The third channel has a larger cross-section than the second channel.

In another feature, the evaporative cooling system comprises a cavity in the substrate support assembly between the first channel and a bottom region of the substrate support assembly. The second channel is connected to the cavity. The cavity is connected to the outlet.

In other features, the evaporative cooling system comprises a third channel arranged in the substrate support assembly above the second channel, and a cavity in the substrate support assembly between the first channel and a bottom region of the substrate support assembly. The second channel is connected to the third channel and to the cavity. The third channel and the cavity are connected to respective vents in the substrate support assembly.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows a first example of a substrate processing system according to the present disclosure;

FIG. 1B shows a second example of a substrate processing system according to the present disclosure;

FIGS. 2A and 2B show a first design of an evaporative cooling system according to the present disclosure;

FIG. 3 shows a cross-sectional view of the first design;

FIG. 4 shows a second design of an evaporative cooling system according to the present disclosure;

FIG. 5 shows a top down view of a first example of the second design that uses bifilar channels;

FIG. 6. shows a cross-sectional view of the first example;

FIG. 7 shows a top down view of a second example of the second design that uses spiral shaped channels;

FIG. 8. shows a cross-sectional view of the second example;

FIG. 9 shows a cross-sectional view of a first example of a third design of an evaporative cooling system according to the present disclosure with a vapor channel added above the first design of FIGS. 2A, 2B, and 3;

FIG. 10 shows a cross-sectional view of a second example of the third design with a vapor channel added above the second design of FIGS. 4-8;

FIG. 11 shows a top down view of the added vapor channel of FIG. 10;

FIG. 12 shows a cross-sectional view of the channels of FIG. 11;

FIG. 13 shows a top down view of a fourth design of an evaporative cooling system according to the present disclosure including a cavity under the second design of FIGS. 4-8;

FIG. 14 shows a cross-sectional view of the fourth design;

FIG. 15 shows a cross-sectional view of the cavity of FIG. 13;

FIG. 16 shows a cross-sectional view of a fifth design of an evaporative cooling system according to the present disclosure including phase separators added to the fourth design;

FIGS. 17A and 17B show examples of control systems for controlling the evaporative cooling systems of FIG. 2A-16; and

FIG. 18 shows an example of a method of controlling the evaporative cooling systems of FIGS. 2A-17B.

In the drawings, reference numbers may be reused to identify similar and/or identical elements.

### DETAILED DESCRIPTION

A cooling fluid is typically used to cool electrostatic chucks (ESCs). The cooling systems of the present disclosure use a specially designed evaporator inside an ESC in conjunction with a refrigerant fluid. Various examples of the evaporators are described below. In particular, cryogenic liquids (i.e., liquids with a normal boiling point below -130° F. (-90° C.)) are evaporated within the ESC structure to provide cooling in a controlled manner leading to efficient and repeatable cooling with effective heat transfer from the substrate to the cooled region. The cooling systems remove relatively high heat loads from the ESC with operation down to cryogenic temperatures. The cooling systems resolve issues with two-phase flow and provide for efficient use of the cooling capacity of the cryogenic fluids. The cooling capacity of the cooling systems is much higher at temperatures below -20° C. than systems that rely on heat transfer to a cooling fluid.

ESC cooling is typically performed either by high-pressure cooled gases or by a variety of liquid coolants. Disadvantages of these methods include limited cooling capacity and/or limited temperature range of operation of these methods. For example, closed cycle liquid chillers become very expensive as operational temperatures drop below -20° C. due to the need for multiple stages of cooling. Coolants must be materials that exist as liquids in extreme temperature ranges such as -80° C. to 80° C. and that are also not unacceptable due to corrosion or toxicity concerns. Such coolants are few and expensive. Alternatively, closed-flow of gases may be used. However, to achieve cooling in the range of 1-5kW, the gas flow required is relatively large, requiring the gas to be compressed to pressures in the range of hundreds of pounds per square inch.

For pure materials, latent heats of vaporization per kilogram are typically much higher than the enthalpy change on heating the medium by for example 20° C., which can be close to the maximum amount used in ESCs due to thermal uniformity considerations. This is why evaporation of a working medium is the cooling method used in most refrigeration systems. However, evaporation at the point of use (i.e., the ESC) has typically not been used. This is because there is a need to evaporate a considerable flow of liquid in a limited space. Flowing a boiling liquid through a closed loop can lead to two-phase flow, which is relatively difficult to control in a stable manner. Depending on surface energies involved, either foam formation occurs or more usually plug flow is established with alternating plugs of gas and liquid, with the gaseous region expanding as the fluid boils. Accordingly, the velocity of these plugs increases dramatically along cooling channels. Likewise, cooling effectiveness decreases, and a relatively large back pressure develops. Therefore, unless the design provides for increasing channel cross sectional area, such a design is fraught with issues of heat transfer uniformity. Instead, as explained below, the evaporative cooling systems of the present disclosure provide more controlled evaporation.

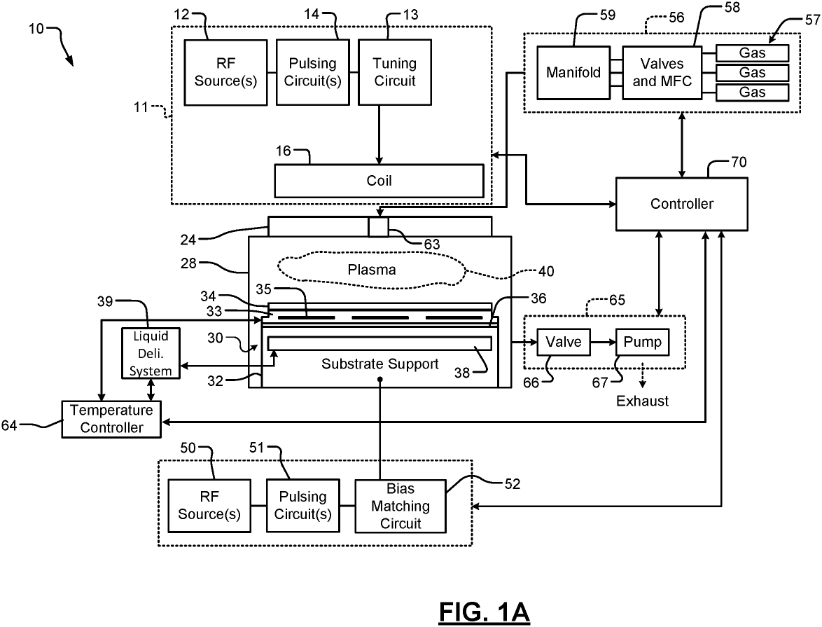

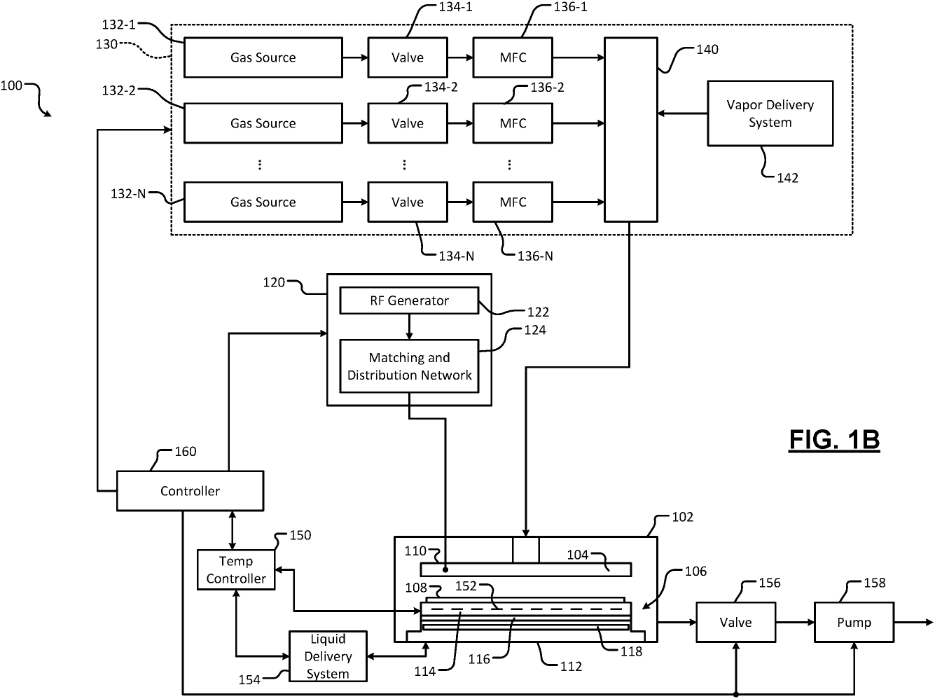

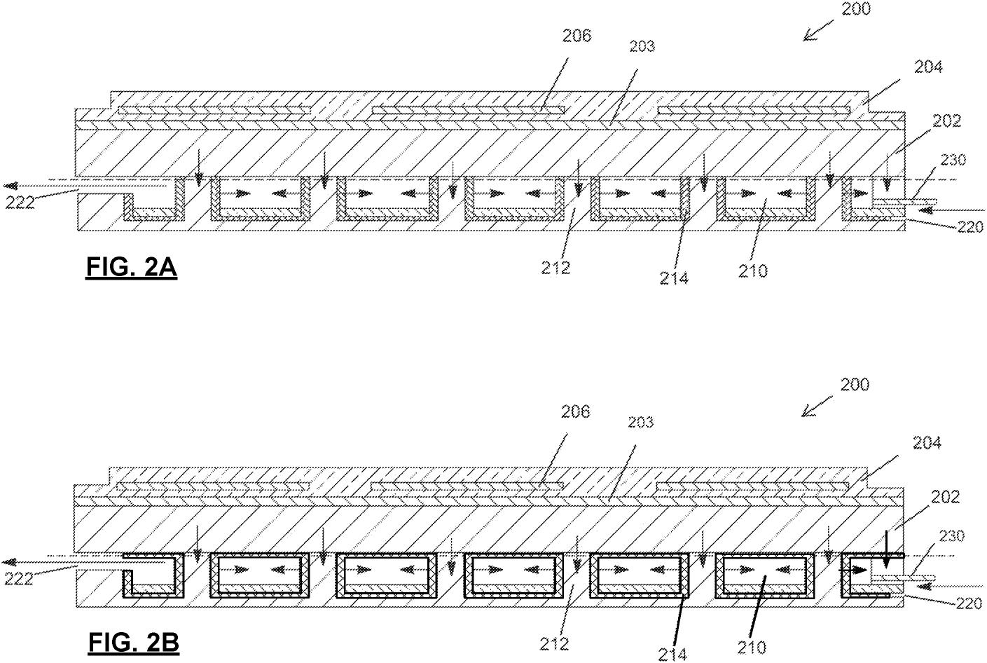

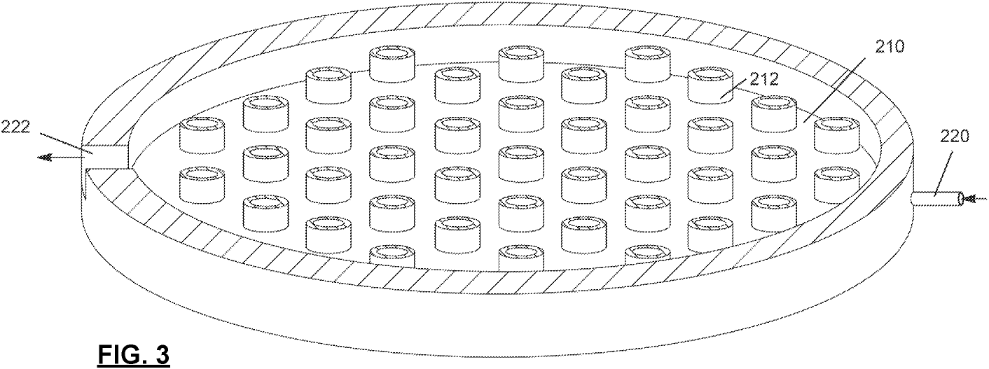

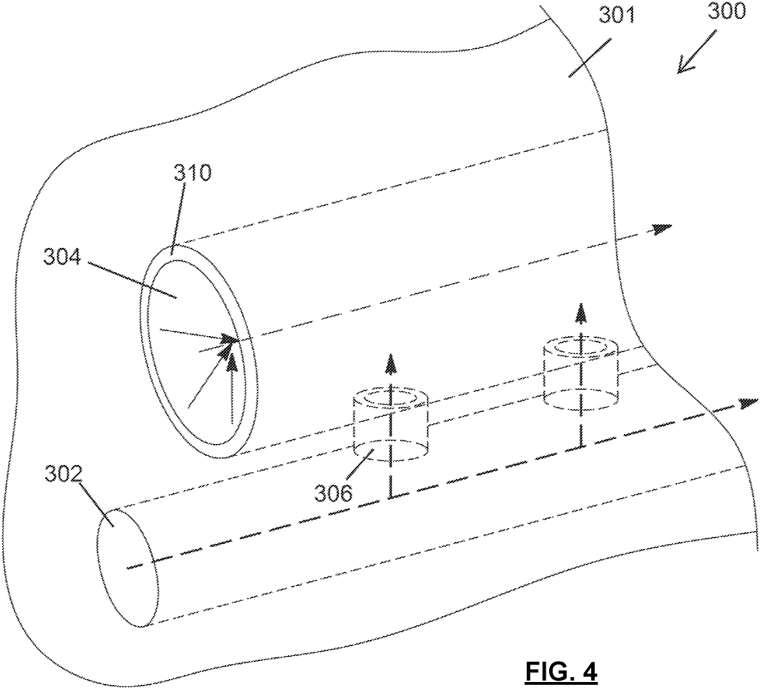

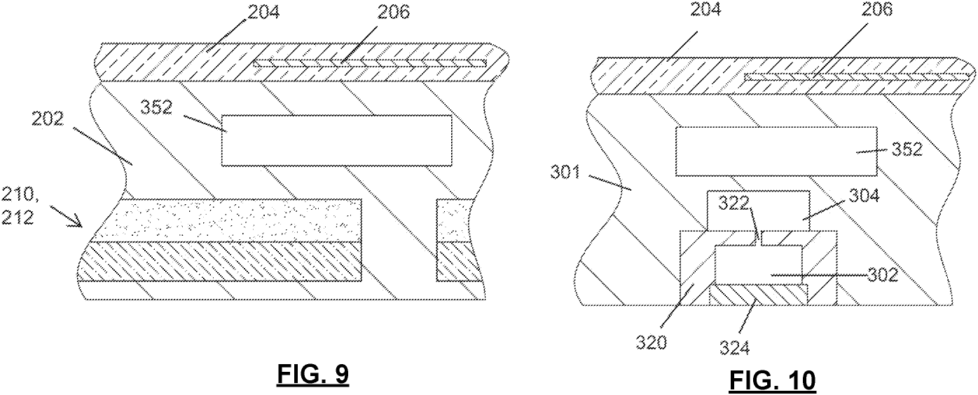

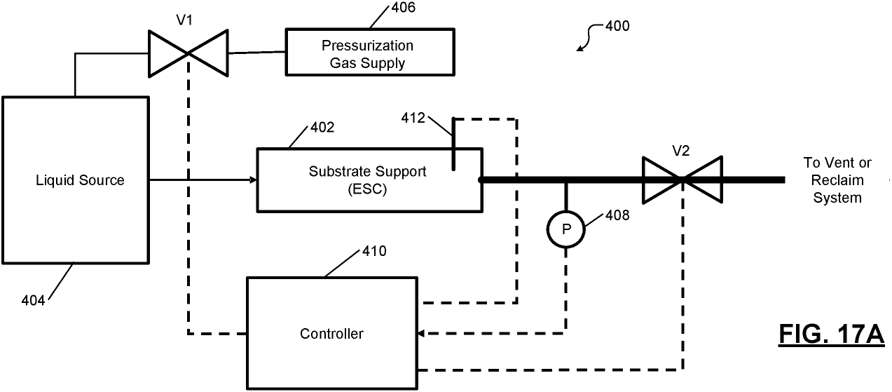

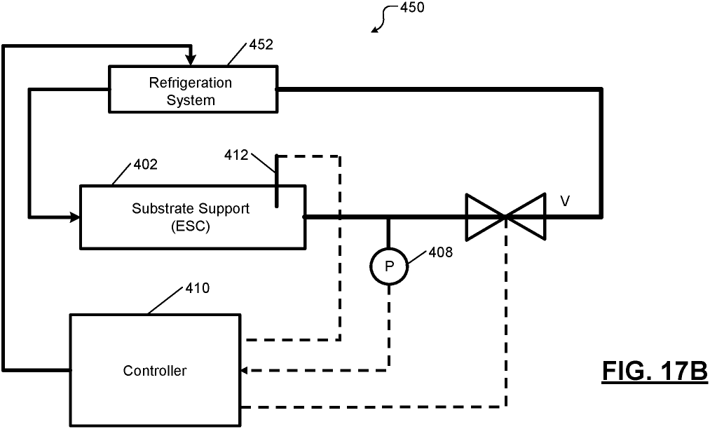

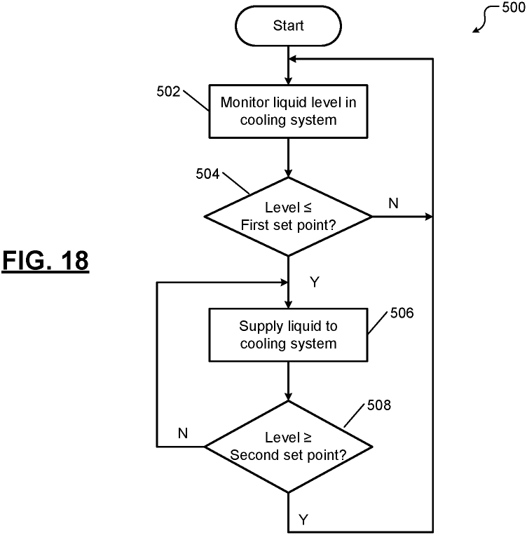

The present disclosure is organized as follows. Initially, examples of substrate processing systems in which the cooling systems of the present disclosure can be used are shown and described with reference to FIGS. 1A and 1B. Thereafter, an example of a cooling system according to a first design is shown and described with reference to FIGS. 2A, 2B, and 3. An example of a cooling system according to a second design is shown and described with reference to FIGS. 4-8. Additional designs are shown and described with reference to FIGS. 9-16. Examples of control systems used to control the various cooling systems is shown and described with reference to FIGS. 17A and 17B. A method of controlling the various cooling systems is shown and described with reference to FIG. 18.

FIG. 1A shows an example of a substrate processing system 10 that uses inductively coupled plasma to etch substrates such as semiconductor wafers according to the present disclosure. The substrate processing system 10 includes a coil driving circuit 11. In some examples, the coil driving circuit 11 includes an RF source 12, a pulsing circuit 14, and a tuning circuit (i.e., matching circuit) 13. The pulsing circuit 14 controls a transformer coupled plasma (TCP) envelope of an RF signal generated by the RF source 12 and varies a duty cycle of TCP envelope between 1% and 99% during operation. The pulsing circuit 14 and the RF source 12 can be combined or separate.

The tuning circuit 13 may be directly connected to an inductive coil 16. While the substrate processing system 10 uses a single coil, some substrate processing systems may use a plurality of coils (e.g., inner and outer coils). The tuning circuit 13 tunes an output of the RF source 12 to a desired frequency and/or a desired phase, and matches an impedance of the coil 16.

A dielectric window 24 is arranged along a top side of a processing chamber 28. The processing chamber 28 comprises a substrate support (or pedestal) 30 to support a substrate 34. The substrate support 30 may include an electrostatic chuck (ESC), or a mechanical chuck or other type of chuck. The substrate support 30 comprises a baseplate 32. A ceramic plate 33 is arranged on a top surface of the baseplate 32. A thermal resistance layer 36 may be arranged between the ceramic plate 33 and the baseplate 32. The substrate 34 is arranged on the ceramic plate 33 during processing. A plurality of heaters 35 is arranged in the ceramic plate 33 to heat the substrate 34 during processing. For example, the heaters 35 comprise printed traces embedded in the ceramic plate 33.

The baseplate 32 further includes an evaporative cooling system 38 to cool the substrate support 30. The evaporative cooling system 38 uses a liquid supplied by a liquid delivery system 39 to cool the substrate support 30. The evaporative cooling system 38 can include any one of the evaporative cooling systems described below with reference to FIG. 2A-15.

A process gas is supplied to the processing chamber 28, and plasma 40 is generated inside of the processing chamber 28. The plasma 40 etches an exposed surface of the substrate 34. An RF source 50, a pulsing circuit 51, and a bias matching circuit 52 may be used to bias the substrate support 30 during processing to control ion energy.

A gas delivery system 56 may be used to supply a process gas mixture to the processing chamber 28. The gas delivery system 56 may include process and inert gas sources 57, a gas metering system 58 such as valves and mass flow controllers, and a manifold 59. A gas injector 63 may be arranged at a center of the dielectric window 24 and is used to inject gas mixtures from the gas delivery system 56 into the processing chamber 28. Additionally or alternatively, the gas mixtures may be injected from the side of the processing chamber 28.

A temperature controller 64 may be connected to the heaters 35 and may be used to control the heaters 35 to control a temperature of the substrate support 30 and the substrate 34. The temperature controller 64 may communicate with the liquid delivery system 39 to control liquid flow through the evaporative cooling system 38 to cool the substrate support 30. For example, as shown and described with reference to 17A, the liquid delivery system 39 may include a liquid source, a pressurized gas supply, valves, and a pressure sensor. For example, as shown and described with reference to 17B, the liquid delivery system 39 may include a refrigeration system. The evaporative cooling system 38 may include a level sensor (e.g., elements 230 and 412 shown in FIGS. 2A, 2B, 17A, and 17B) to sense liquid level in the evaporative cooling system 38 as described below in detail. The temperature controller 64 may control the liquid flow through the evaporative cooling system 38 based on feedback from the level sensor and the pressure sensor.

An exhaust system 65 includes a valve 66 and pump 67 to control pressure in the processing chamber 28 and/or to remove reactants from the processing chamber 28 by purging or evacuation. A controller 70 may be used to control the etching process. The controller 70 controls the components of the substrate processing system 10. The controller 70 monitors system parameters and controls delivery of the gas mixture; striking, maintaining, and extinguishing the plasma; removal of reactants; supply of cooling liquid; and so on. Additionally, the controller 70 may control various aspects of the coil driving circuit 11, the RF source 50, and the bias matching circuit 52, and so on.

FIG. 1B shows another example of a substrate processing system 100 comprising a processing chamber 102 configured to generate capacitively coupled plasma. While the example is described in the context of plasma enhanced chemical vapor deposition (PECVD), the teachings of the present disclosure can be applied to other types of substrate processing such as atomic layer deposition (ALD), plasma enhanced ALD (PEALD), CVD, or also other processing including etching.

The substrate processing system 100 comprises the processing chamber 102 that encloses other components of the substrate processing system 100 and contains RF plasma (if used). The processing chamber 102 comprises an upper electrode 104 and an electrostatic chuck (ESC) 106 or other type of substrate support. During operation, a substrate 108 is arranged on the ESC 106.

For example, the upper electrode 104 may include a gas distribution device 110 such as a showerhead that introduces and distributes process gases into the processing chamber 102. The gas distribution device 110 may include a stem portion including one end connected to a top surface of the processing chamber 102. A base portion of the showerhead is generally cylindrical and extends radially outwardly from an opposite end of the stem portion at a location that is spaced from the top surface of the processing chamber 102. A substrate-facing surface or faceplate of the base portion of the showerhead includes a plurality of outlets or features (e.g., slots or through holes) through which vaporized precursor, process gas, cleaning gas, or purge gas flows.

The ESC 106 comprises a baseplate 112 that acts as a lower electrode. A ceramic plate 114, which includes heaters 152 to heat the substrate 108, is arranged on a top surface of the baseplate 112. The heaters 152 comprise printed traces embedded in the ceramic plate 114. A thermal resistance layer 116 may be arranged between the ceramic plate 114 and the baseplate 112. The baseplate 112 includes an evaporative cooling system 118 to cool the ESC 106. The evaporative cooling system 118 can include any one of the evaporative cooling systems described below with reference to FIG. 2A-15.

If plasma is used, an RF generating system (or an RF source) 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example, the RF generating system 120 may include an RF generator 122 that generates RF power that is fed by a matching and distribution network 124 to the upper electrode 104 or the baseplate 112. In other examples, while not shown, the plasma may be generated inductively or remotely and then supplied to the processing chamber 102.

A gas delivery system 130 includes one or more gas sources 132-1, 132-2, ..., and 132-N (collectively gas sources 132), where N is an integer greater than zero. The gas sources 132 are connected by valves 134-1, 134-2, ..., and 134-N (collectively valves 134) and mass flow controllers 136-1, 136-2, ..., and 136-N (collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102. The gas sources 132 may supply process gases, cleaning gases, or purge gases.

A temperature controller 150 may be used to control the heaters 152 to control a temperature of the ESC 106 and the substrate 108. The temperature controller 150 may communicate with a liquid delivery system 154 to control liquid flow through the evaporative cooling system 118 to cool the ESC 106. For example, as shown and described with reference to FIG. 17A, the liquid delivery system 154 may include a liquid source, a pressurized gas supply, valves, and a pressure sensor. For example, as shown and described with reference to FIG. 17B, the liquid delivery system 154 may include a refrigeration system. The evaporative cooling system 118 may include a level sensor (e.g., elements 230 and 412 shown in FIGS. 2A, 2B, 11A, and 17B) to sense liquid level in the evaporative cooling system 118 as described below in detail. The temperature controller 150 may control the liquid flow through the evaporative cooling system 118 based on feedback from the level sensor and the pressure sensor.

A valve 156 and pump 158 may be used to evacuate reactants from the processing chamber 102. A system controller 160 controls the components of the substrate processing system 100.

In the following evaporative cooling systems shown in FIG. 2A-16, a liquid is evaporated in a controlled manner by transfer to a wicking surface as explained below in detail. Various implementations are provided in FIG. 2A-16 as exemplars. Examples of control systems used to control the various evaporative cooling systems are shown in FIGS. 17A and 17B. A method to control the various evaporative cooling systems is shown in FIG. 18.

FIGS. 2A, 2B, and 3 show a first design of an evaporative cooling system according to the present disclosure. In FIG. 2A, an ESC 200 comprises a baseplate 202. A ceramic plate 204 is arranged on the baseplate 202. A plurality of heaters 206 (e.g., printed traces) is arranged within the ceramic plate 204. A thermal resistance layer 203 may be arranged between the heaters 206 and the baseplate 202. A substrate (not shown) is arranged on the ceramic plate 204 during processing.

In the baseplate 202, a cavity 210 is defined, which is shown in further detail in FIG. 3. The baseplate 202 can be made of a high thermal conductivity material including a metal such as aluminum or titanium, or an alloy such as AlSiC or SiC. FIG. 3 shows a cross-section of the baseplate 202 taken along a dotted line shown in FIG. 2A. In the cross-section, a top portion of the cavity 210 is shown open for illustrative purposes.

As FIG. 3 shows, the cavity 210 is in the form of a cylinder with height less than its diameter. The cavity 210 includes pillars 212 that bridge the cavity 210 from top to bottom. The pillars 212 can also be called projections or protrusions. For example only, the pillars 212 are shown as being cylindrical. Alternatively, the pillars 212 can have other shapes. The pillars 212 have a shape with a relatively high surface area.

The interior of the cavity 210 is covered with a wicking material 214. In FIG. 2B, the wicking material 214 additionally lines the top surfaces of the pillars 212, which allows heat transfer from the liquid over a wider area. For example, the wicking material 214 can comprise metal coatings having a relatively high surface area. For example, the wicking material 214 can include plasma-sprayed or twin wire arc sprayed aluminum. Alternatively, electroplating can be used for enhancing the surface area of the wicking material 214. In other examples, the wicking material 214 can comprise sintered glass beads or sintered polymer spheres (e.g., polyethylene), where the beads in both cases can be about 10 to 300um in diameter.

The cavity 210 includes one or more inlet ports 220 to receive the liquid to be evaporated and one or more outlet ports 222 for removal of evaporated vapor. The outlet port is larger than the inlet port 220. Heat flows from an upper region of the baseplate 202 above the cavity 210 to the pillars 212. The liquid in the cavity 210 transfers to the wicking material 214 and is evaporated in a controlled manner by the heat transferred from the pillars 212 to the wicking material 214.

The cavity 210 includes one or more level sensors 230 that are used with a control system (see examples shown in FIGS. 17A and 17B) to maintain an approximately constant level of liquid in the lower part of the cavity 210. The liquid rises up the surfaces of the wicking material 214 and evaporates on the surfaces of the wicking material 214 in a controlled manner without significant bubble formation. The evaporated gas exits the cavity 210 from the vents (i.e., the outlet ports 222) and can be further used to cool the ESC 200 as described below.

The design maximizes the length of the boundary between the cavity material and the cavity space (to provide a maximum wicking area) while providing for sufficient thermal conduction from the wicking material 214 to a region of the ESC 200 above the cavity 210.

Stated generally, a substrate support assembly such as the ESC 200 comprises the baseplate 202 and the ceramic plate 204 arranged on the baseplate 202. The ceramic plate 204 includes one or more heaters 206 to heat the substrate arranged on the ceramic plate 204 during processing. The baseplate 202 comprises the cavity 210 between (or defined by) an upper region, a lower region, and sidewalls of the baseplate 202. The cavity 210 is cylindrical, and the height of the cavity 210 is less than the diameter of the cavity 210. The cavity 210 extends radially along the diameter of the baseplate 202. A plurality of the pillars 212 is arranged in the cavity 210 between the upper and lower regions of the baseplate 202. For example, the pillars 212 are cylindrical and extend from the bottom of the cavity 210 to the top of the cavity 210. For example, the pillars 212 extend vertically (i.e., perpendicularly) from the bottom of the cavity 210 to the top of the cavity 210. The pillars 212 are coated with the wicking material 214. The baseplate 202 comprises the inlet 220 to supply the liquid to the cavity 210 and the outlet 222 to vent vapor of the liquid from the baseplate 202. The inlet 220 is smaller in size than the outlet 222. The inlet 220 is adjacent (i.e., proximate) to the bottom of the cavity 210, and the outlet 222 is adjacent (i.e., proximate) to the top of the cavity 210.

FIG. 4 shows a second design of an evaporative cooling system according to the present disclosure. In the second design, an ESC 300 is provided with pairs of parallel channels arranged in the baseplate of the ESC 300. In the example shown, a pair of channels including a lower channel 302 and an upper channel 304 is disposed in the baseplate of the ESC 300. The lower and upper channels 302, 304 are respectively also called first and second channels or liquid and vapor channels throughout the present disclosure.

The lower and upper channels 302, 304 are provided at intervals with small connectors (also called connecting channels) 306 generally extending perpendicularly between the lower and upper channels 302, 304. Liquid flows through the lower channel 302 and is not intended to boil therein. Sufficient liquid flow is maintained in the lower channel 302 to minimize boiling of the liquid in the lower channel 302. The upper channel 304 has a considerably larger cross sectional area than the lower channel 302. In one implementation, the inner walls of the upper channel 304 are coated with a wicking material 310. The wicking material 310 can be similar to the wicking material 214 shown in FIGS. 2A and 2B. In some implementations, the wicking material 310 can be omitted.

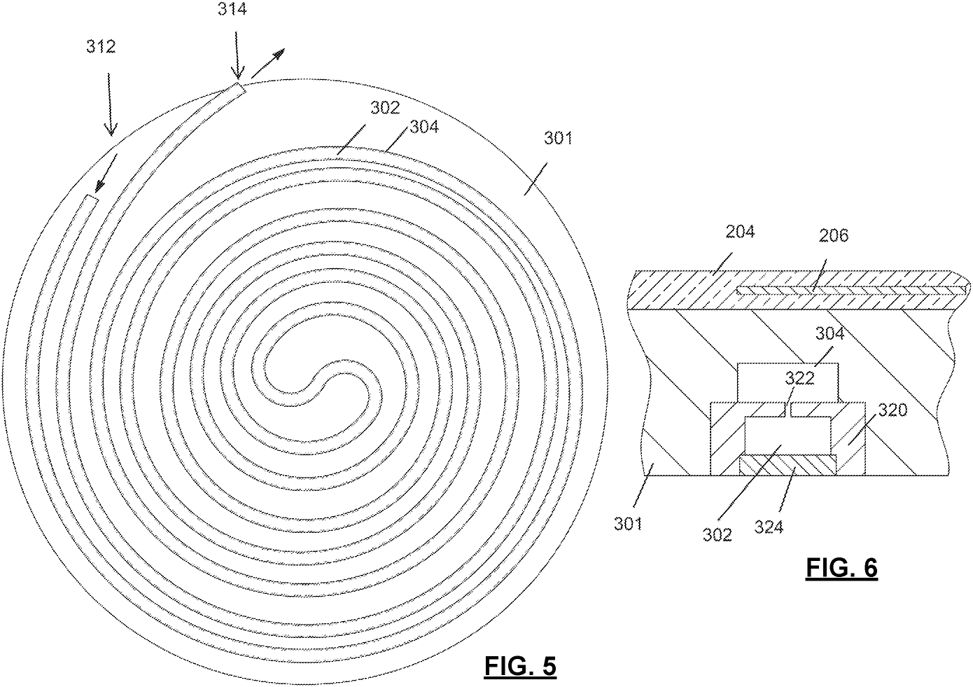

In operation, liquid is forced from the lower channel 302 through the connectors 306 into the larger upper channel 304. Heat flows from an upper region of the baseplate above the upper channel 304 to upper channel 304. Evaporation of the liquid occurs in the upper channel 304, and gas (i.e., vapor) formed due to the evaporation passes along the upper channel 304 to an outlet port (shown in FIG. 5). The configuration of the lower and upper channels 302, 304 and the connectors 306 separate liquid flow from gaseous flow and prevents issues arising from two-phase flow.

The layouts of the lower and upper channels 302, 304 can be such that the liquid delivery channel (i.e., the lower channel 302) is vertically below the gas channel (i.e., the upper channel 304). The layouts are parallel to the plane of the substrate. The lower and upper channels 302, 304 are also parallel to each other.

FIGS. 5 and 6 show a first example of implementing the lower and upper channels 302, 304 in the ESC 300 according to the second design. In FIG. 5, the lower channel 302 (shown by dotted lines) and the upper channel 304 (shown by solid lines) disposed in a baseplate 301 of the ESC 300 are bifilar to minimize temperature gradients. The lower channel 302 includes an inlet 312 for the liquid, and the upper channel 304 includes an outlet 314 for the vapor. The vapor channel (i.e., the upper channel 304) is dead ended. In one implementation, the liquid channel (i.e., the lower channel 302) is dead ended. In another implementation, the liquid channel (i.e., the lower channel 302) is not dead ended. The lower and upper channels 302, 304 are stacked. That is, the vapor channel (i.e., the upper channel 304) is nearer to the substrate (i.e., the upper surface of the ESC 300) and is stacked above the liquid channel (i.e., the lower channel 302). While fabrication of these stacked channels can be challenging, FIG. 6 shows one solution.

In FIGS. 5-14, the lower and upper channels 302, 304 are not drawn to scale. Further, any difference between the size of the lower and upper channels 302, 304 show in top down views and the lower and upper channels 302, 304 show in corresponding cross-sectional views is not actual. As shown in FIG. 4, in FIGS. 5-14, the upper channel 304 has a larger cross sectional area than the lower channel 302. In addition, in FIGS. 5-14, the thermal resistance layer 203 is present but not shown.

In FIG. 6, a rectangular channel 320 disposed in the baseplate 301 of the ESC 300 is closed by a structure which itself includes or defines the liquid channel 302, and nozzles 322 penetrating the structure in the direction of the vapor channel form the connectors 306. This structure is held in the ESC body (i.e., the base plate 301), and the liquid channel 302 is closed by a plate 324.

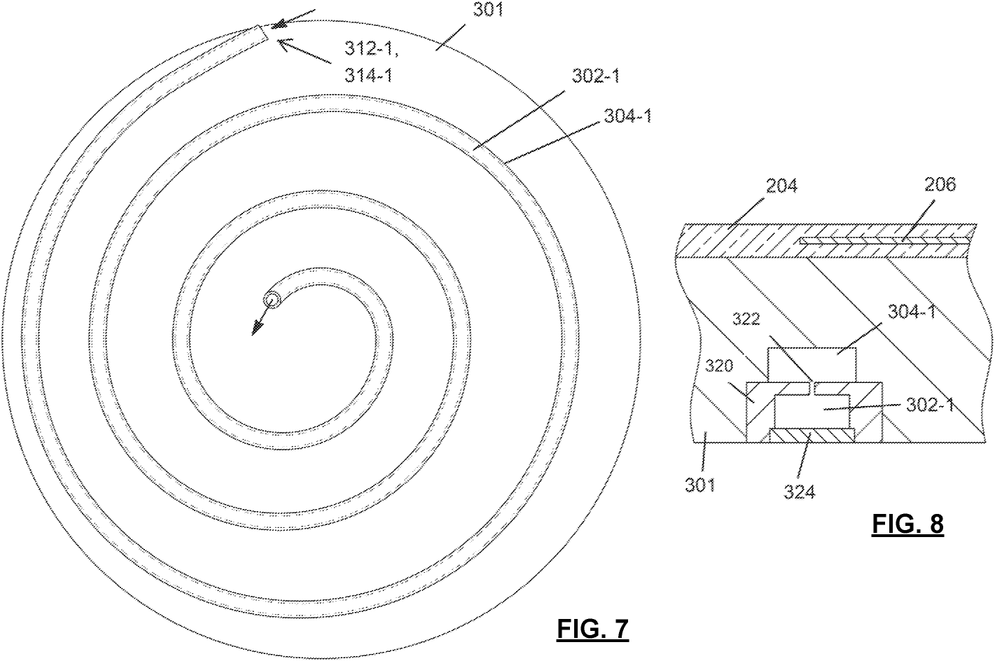

FIGS. 7 and 8 show a second example of implementing the lower and upper channels 302, 304 in the ESC 300 according to the second design. In FIG. 7, the lower and upper channels 302, 304 disposed in the baseplate 301 of the ESC 300 are two separate spiral shaped channels instead of being bifilar channels shown in FIG. 5. A lower channel 302-1 includes an inlet 312-1 for the liquid, and an upper channel 304-1 includes an outlet 314-1 for the vapor. The lower and upper channels 302-1, 304-1 are stacked similar to the channels shown and described above with reference to FIGS. 4-6. The lower and upper channels 302-1, 304-1 are provided at intervals with the connecting channels 306 as shown in FIG. 4 generally extending perpendicularly between the lower and upper channels 302-1, 304-1. The spiral shaped lower and upper channels 302-1, 304-1 are terminated near the center of the baseplate 301. FIG. 8 shows the construction of the stacked lower and upper spiral shaped channels 302-1, 304-1. FIG. 8 is similar to FIG. 6 and is shown for reference only and is therefore not described again.

Throughout the present disclosure, the bifilar lower and upper channels 302, 304 shown in FIG. 5 and the spiral shaped lower and upper channels 302-1, 304-1 shown in FIG. 7 are collectively called the lower and upper channels 302, 304. Further, as already mentioned above, the lower and upper channels 302, 304 are respectively also called first and second channels or liquid and vapor channels throughout the present disclosure. Regardless of the shape (i.e., bifilar or spiral), the lower and upper channels 302, 304 are provided at intervals with the connecting channels 306 generally extending perpendicularly between the lower and upper channels 302, 304.

Stated generally, a substrate support such as the ESC 300 comprises the baseplate 301 and the ceramic plate 204 arranged on the baseplate 301. The ceramic plate 204 includes one or more heaters 206 to heat the substrate arranged on the ceramic plate 204 during processing. The baseplate 301 comprises a first channel (i.e., the liquid channel) 302 arranged in the baseplate 301. The baseplate 301 comprises a second channel (i.e., the vapor channel) 304 arranged above the first tubular channel 302. The first and second channels 302, 304 can be round (tubular), rectangular, or polygonal. The baseplate 301 comprises a plurality of vertical channels (i.e., the connectors) 306 connecting the first channel 302 to the second channel 304. The baseplate 301 comprises an inlet to supply the liquid to the first channel 302 and an outlet to vent vapor of the liquid from the second channel 304. For example, the first and second channels 302, 304 are spiral shaped or bifilar. The first and second channels 302, 304 are arranged parallel to the substrate. The baseplate 301 is cylindrical, and the first and second channels 302, 304 extend radially across the diameter of the baseplate 301. In one implementation, the inlet is connected to a first end of the first channel 302; a second end of the first channel 302 is terminated; a first end of the second channel 304 is terminated; and a second end of the second channel 304 is connected to the outlet. In another implementation, the first end of the second channel 304 is connected to another outlet.

In the second design shown in FIGS. 4-8, control of liquid flow from the liquid channel 302 to the vapor channel 304 can be managed by a sensor that detects excess liquid in the vapor channel 304. In some implementations, a level sensor can be used. Other implementations may use a sensor that detects droplets or plugs of liquid emerging form the vapor channel 304. The level sensors can be of any type. For example, the level sensors can include hot-wire resistance type level sensors. In these sensors, a wire is warmed by a substantially constant electric current (e.g., supplied by the temperature controller 64 or 150 shown in FIGS. 1A and 1B). Contact with liquid (with its greater heat removal capability) sharply reduces the temperature of the wire and increases its resistance, which can be detected as a voltage decrease (e.g., by the temperature controller 64 or 150 shown in FIGS. 1A and 1B). The designs of the present disclosure are not limited by the choice of these sensors, and many other options are possible and may be used.

In the second design shown in FIGS. 4-8 (and also in the first design shown in FIGS. 2A, 2B, and 3), the gas (i.e., vapor) produced in the upper channel 304 by boiling the liquid due to heat from the upper region of the ESC 300 above the upper channel 304 is still at close to boiling temperature and can be used to further control the temperature of the ESC 300. The gas can also be used as a relatively low thermal conductivity (i.e., insulating) medium as shown and described below with reference to FIGS. 9-14.

While a surface on which liquid is evaporating can be very close in temperature to the boiling point of the liquid, this is unlikely to be the desired ESC operating temperature. Accordingly, allowance must be made for there to be a thermal gradient in the ESC. Conversely, the walls of channel containing gas (i.e., vapor) may be at quite a different temperature relative to the gas. Accordingly, the cooling system can be further improved by passing the gas through a further channel layered above and/or below the evaporation system (i.e., above and/or below the upper channel 304 shown in FIGS. 4-8 as well as above and/or below the cavity 210 shown in FIGS. 2A, 2B, and 3). Similar to the upper channel 304, this second gas loop (i.e., additional vapor channel) can be designed to provide the best (i.e., most spatially uniform) pattern of heat removal.

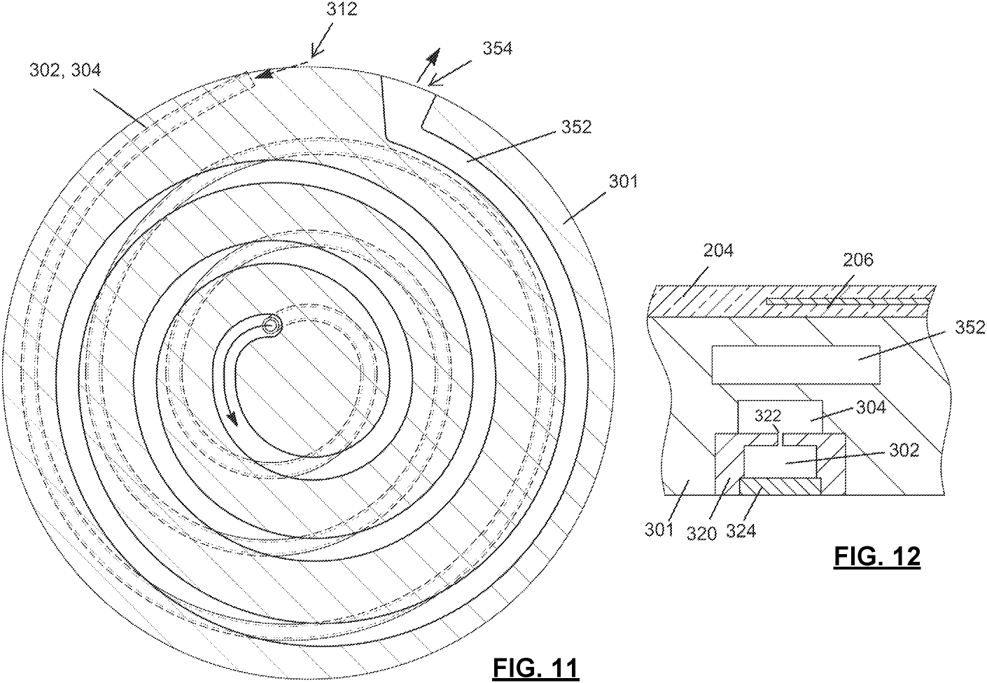

FIGS. 9 and 10 show examples of ESCs comprising a second vapor channel 352 above the evaporator systems shown in FIGS. 2A-3 and 4-8. In FIG. 9, the second vapor channel 352 is disposed above the cavity 210 shown in FIGS. 2A, 2B, and 3. The second vapor channel 352 can be spiral shaped. FIG. 11 shows a top down view of the second vapor channel 352. The second vapor channel 352 provides a thermal gradient in the upper region of the baseplate 202.

In FIG. 10, the second vapor channel 352 is disposed above the upper channel 304 shown in FIGS. 4-8. The second vapor channel 352 is connected to the upper channel 304 and receives vapor from upper channel 304. The second vapor channel 352 can be spiral shaped. The second vapor channel 352 spirals in opposite direction relative to the lower and upper channels 302, 304. The second vapor channel 352 is arranged parallel to the lower and upper channels 302, 304. The FIG. 11 shows a top down view of the second vapor channel 352. The second vapor channel 352 provides a thermal gradient in the upper region of the baseplate 301.

FIGS. 11 and 12 show an example of the second vapor channel 352 implemented in the second design of the cooling system shown in FIGS. 4-8. FIG. 11 shows a top down view of an example of the second vapor channel 352. In the example, while the lower and upper channels 302, 304 are shown as being spiral shaped (see FIGS. 7 and 8), the lower and upper channels 302, 304 can also be bifilar as shown in FIGS. 5 and 6. The lower and upper channels 302, 304 are stacked as already described. The second vapor channel 352 is stacked above the upper channel 304. The upper channel 304 is dead ended. In one implementation, the lower channel 302 is dead ended. In another implementation, the lower channel 302 is not dead ended. One end (i.e., the open end) of the upper channel 304 is connected to the second vapor channel 352 near the center of the baseplate 301. The opposite end of the second vapor channel 352 vents the vapor through an outlet 354. FIG. 12 is similar to FIG. 10 and is also similar to FIG. 6 except for the addition of the second vapor channel 352 and is therefore not described again.

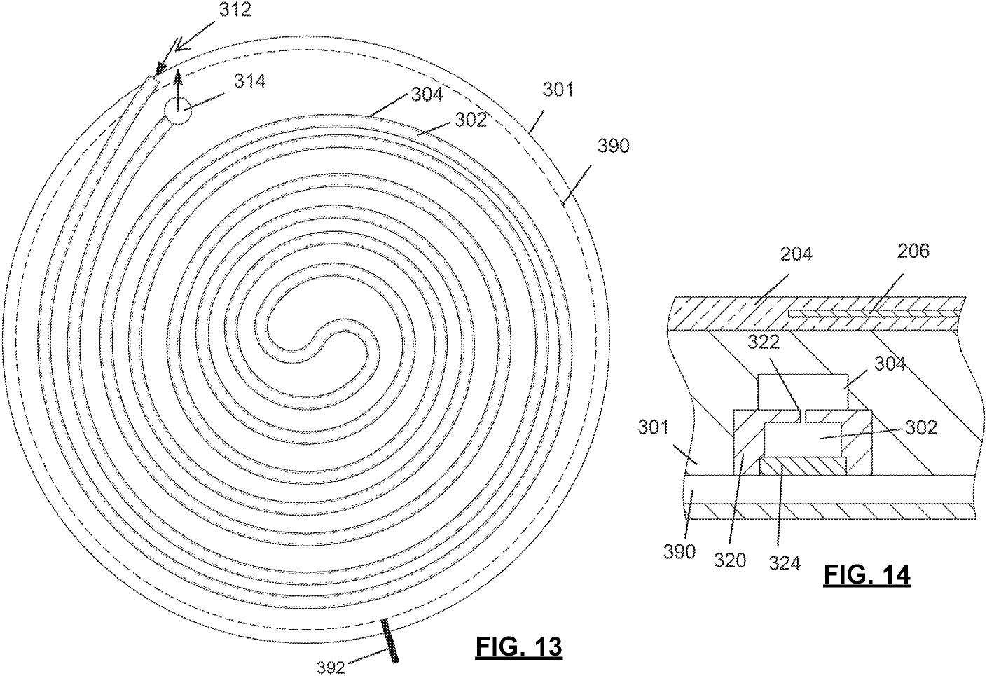

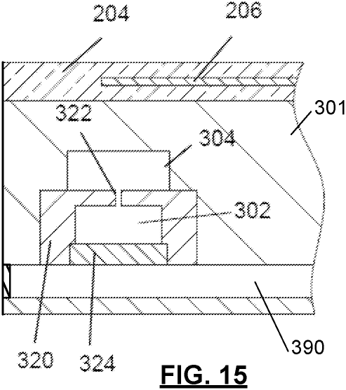

FIGS. 13-15 show an example of implementing a thermal insulation layer under the cooling systems described above to reduce parasitic heating of the liquid from the bottom region of the baseplate of the ESC. The example is shown for the cooling system shown FIGS. 4-8. While not shown, a similar design may be implemented in the cooling system shown FIGS. 2A, 2B, and 3. In the example, a cavity 390 is defined in the baseplate 301 below the lower channel 302 (i.e., between the lower channel 302 and the bottom portion of the baseplate 301). For example, the cavity 390 may be a simple cylindrical space as shown. Alternatively, while not shown, vapor flow may also be channelized by suitable walls. The vapor exits the upper channel 304 from the outlet 314 into the cavity 390 and exits the cavity 390 from an outlet 392. While the lower and upper channels 302, 304 are shown as being bifilar, the lower and upper channels 302, 304 can instead be spiral shaped as shown in FIGS. 7 and 8. FIG. 14 is similar to FIG. 6 except for the addition of the cavity 390 and is therefore not described again. FIG. 15 shows a cross-sectional view of the cavity 390.

The following description explicitly recites the connections between the second vapor channel 352 and/or the cavity 390 and the elements of the cooling systems shown in FIGS. 2A-3 and 4-8 when the second vapor channel 352 and/or the cavity 390 are added to the cooling systems shown in FIG. 2A-3 and FIGS. 4-8.

When the second vapor channel 352 shown in FIGS. 9 and 11 is added to the cooling system shown in FIGS. 2A, 2B, and 3, the baseplate 202 further comprises a channel (i.e., the second vapor channel) 352 arranged in the baseplate 202 above the cavity 210. The channel 352 can be round (i.e., tubular), rectangular, or polygonal. The outlet 222 is connected to a first end of the channel 352, and a second end of the channel 352 is connected to a vent in the baseplate 202. For example, the baseplate 202 and the cavity 210 are cylindrical; and the channel 352 is spiral or bifilar. The cavity 210 and the channel 352 extend radially along the diameter of the baseplate 202.

When the cavity 390 shown in FIG. 13 is added to the cooling system shown in FIGS. 2A, 2B, and 3, the baseplate 202 further comprises the cavity 390 (called a second cavity 390 to distinguish it from the cavity 210) between the cavity 210 and the lower region of the baseplate 202. The outlet 222 is connected to the second cavity 390, and the second cavity 390 is connected to a vent in the baseplate 202.

When both the second vapor channel 352 shown in FIGS. 9 and 11 and the cavity 390 shown in FIG. 13 are added to the cooling system shown in FIGS. 2A, 2B, and 3, the baseplate 202 further comprises the channel (i.e., the second vapor channel) 352 arranged in the baseplate 202 above the cavity 210. The baseplate 202 further comprises the cavity 390 (called a second cavity 390 to distinguish it from the cavity 210) between the cavity 210 and the lower region of the baseplate 202. The outlet 222 is connected to a first end of the channel 352 and to the second cavity 390. The second cavity 390 and a second end of the channel 352 are connected to respective vents in the baseplate 202. The channel 352 is spiral or bifilar. The baseplate 202 is cylindrical; and the cavity 210, the channel 352, and the second cavity 390 extend radially across the diameter of the baseplate 202.

When the second vapor channel 352 shown in FIGS. 10-12 is added to the cooling system shown in FIGS. 4-8, the inlet in the baseplate 301 is connected to a first end of the first channel (i.e., the liquid channel) 302, and a second end of the first channel 302 is terminated. The baseplate 301 further comprises the second vapor channel (called a third channel) 352 arranged above the second channel (i.e., the vapor channel) 304. A first end of the second channel 304 is connected to a first end of the third channel 352. A second end of second channel 304 is terminated. A second end of the third channel 352 is connected to the outlet in the baseplate 301. The third channel 352 has a larger cross-section than the second channel 304. The third channel 352 is spiral or bifilar. The baseplate 301 is cylindrical; and the first, second, and third channels 302, 304, 352 extend radially across the diameter of the baseplate 301.

When the cavity 390 shown in FIGS. 13-14 is added to the cooling system shown in FIGS. 4-8, the inlet in the baseplate 301 is connected to the first end of the first channel (i.e., the liquid channel) 302. The second end of the first channel 302 is terminated. The baseplate 301 further comprises the cavity 390 between the first channel 302 and a bottom region of the baseplate 301. A first end of the second channel (i.e., the vapor channel) 304 is connected to the cavity 390. A second end of second channel 304 is terminated. The cavity 390 is connected to the outlet in the baseplate 301. The baseplate 301 is cylindrical; and the first and second channels 302, 304 and the cavity 390 extend radially across the diameter of the baseplate 301.

When both the second vapor channel 352 and the cavity 390 shown in FIGS. 10-14 are added to the cooling system shown in FIGS. 4-8, the inlet in the baseplate 301 is connected to a first end of the first channel 302. A second end of the first channel 302 is terminated. The baseplate 301 further comprises the third channel 352 arranged above the second channel 304. The baseplate 301 further comprises the cavity 390 between the first channel 390 and the bottom region of the baseplate 301. A first end of the second channel 304 is connected to a first end of the third channel 352 and to the cavity 390. A second end of second channel 352 is terminated. A second end of the third channel 352 and the cavity 390 are connected to respective vents in the baseplate 301. The third channel 352 has a larger cross-section than the second channel 304. The third channel 352 is spiral or bifilar. The baseplate 301 is cylindrical; and the first, second, and third channels 302, 304, 352 and the cavity 390 extend radially across the diameter of the baseplate 301.

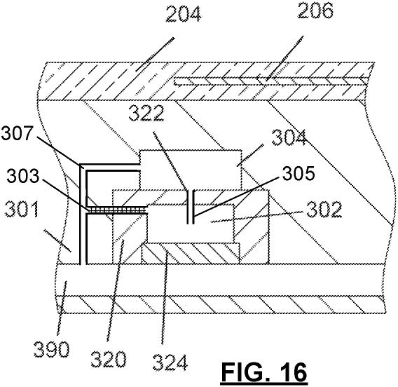

FIG. 16 shows a cross-sectional view of another example of an evaporative cooling system that includes phase separators that separate the vapor from the liquid and that ensure that only liquid can enter into the upper channel 304 from the lower channel 302. FIG. 16 is similar to FIG. 14 except that porous plugs 303 are added to the lower channel 302 and straw-like passages 305 are added to extend the nozzles 322 between the upper and lower channels 304, 302 as shown.

For example, the porous plugs 303 can include sintered metal elements that allow vapor to flow through relatively easily and are more resistant to liquid flow than vapor flow. The porous plugs 303 are arranged closer to the upper end of the lower channel 302. For example, the porous plugs 303 are arranged as close to the nozzles 322 as possible. The porous plugs 303 are connected to a passage 307 that connects the outlet 314 of the upper channel 304 to the cavity 390. Accordingly, any vapor that may form in the lower channel 302 can bleed through the porous plug 303 into the cavity 390 instead of entering the upper channel 304, and only the liquid from the lower channel 302 can enter into the upper channel 304.

To further ensure the separation of the vapor and liquid in the lower channel 302 and to ensure that only liquid from the lower channel 302 can enter the upper channel 304, the nozzles 322 between the upper and lower channels 304, 302 can be extended downwards into the lower channel 302 by the straw-like passages 305. For example, the straw-like passages 305 can extend from the nozzles 322 into the lower channel 302 at least below the level of the porous plugs 303 and preferably to the center of the lower channel 322.

Liquids that can be used in the cooling systems of FIGS. 1-16 for the purposes described herein can include liquid gases and refrigerant fluids. Examples of the liquid gases include ammonia, liquid nitrogen, liquid argon, or other liquid noble (i.e., inert) gases. Examples of the refrigerant fluids include R404a and R134a. Higher boiling point fluids can also be used for ESCs configured to operate at elevated temperatures.

FIG. 17A shows a system 400 that can be used with the cooling systems of FIG. 2A-16 for modulating the boiling point of the liquid according to the present disclosure. Some modulation of the boiling point of the liquid can be obtained by changing pressure at which the liquid evaporates. To achieve such modulation, the system 400 provides back pressure regulation using valves. For example, the valves can include spring-operated check valves or computer-programmable, actively controlled throttling valves.

The system 400 comprises an ESC 402, which can be any of the ESCs described above with reference to FIG. 2A-15, a liquid source 404, a pressurization gas supply 406, a first valve V1, a second valve V2, and a controller 410 (e.g., controller 64, 70, 170, or 150 shown in FIGS. 1A and 1B ).

The liquid source 404 supplies the liquid (e.g., a liquid gas or a refrigerant fluid described above) to the ESC 402 (e.g., to the cavity 210 shown in FIG. 2A-3 or to the lower channel 302 shown in FIGS. 4-14). The pressurization gas supply 406 supplies a pressurization gas to the liquid source 404 via the first valve V1. The first valve V1 is used to control the liquid pressure while the second valve V2 is a variable valve and is used to control the liquid flow through the system 400.

A pressure sensor 408 measures the system pressure P and provides it to the controller 410. The controller 410 opens the first valve V1 to supply the pressurization gas from the pressurization gas supply 406. The pressurization gas has a pressure greater than a maximum pressure required until P reaches a preset level.

The height (i.e., level) of the liquid in the ESC 402 (e.g., in the cavity 210 shown in FIG. 2A-3 or in the lower channel 302 shown in FIGS. 4-14) is controlled by the second valve V2. When a level sensor 412 (e.g., level sensor 230 shown in FIGS. 2A and 2B or a similar sensor used in FIGS. 4-14) indicates that the liquid level in the ESC 402 (e.g., in the cavity 210 shown in FIG. 2A-3 or in the lower channel 302 shown in FIGS. 4-8) is below a first set point, the controller 410 increases the conductance through the second valve V2, which allows an increased flow of the liquid from the liquid source 404 into the ESC 402. When the liquid level in the ESC 402 reaches a second set point, the controller 410 partially closes the second valve V2.

The pressure change can provide a considerable change in the evaporation temperature of the liquid. For example, if ammonia is used as the liquid, the boiling point may be varied from -30C to 10C on increasing the pressure from 1 bar to 4 bar. Alternatively, refrigerant R404a can be used between a boiling temperature of -50C and 0C over a similar pressure range.

In some embodiments, the vapor produced by boiling the liquid can be recovered, cooled, liquefied, and returned to the evaporative cooling system in the ESC 402. The ESC 402 then functions as an evaporator of a closed-loop refrigeration system, being enabled to operate efficiently and uniformly by the cooling systems of the present disclosure implemented in the ESC 402. In other embodiments, the vapor may be discharged, either to vent to the atmosphere or, in some cases such as nitrogen, for use in facilities of the tool (where dry nitrogen is used throughout the facility by boiling liquid nitrogen).

FIG. 17B shows a system 450 that can be used with the cooling systems of FIG. 2A-16. The system 450 is similar to the system 400 shown in FIG. 17A except that the system 450 includes a refrigeration system 452 instead of the elements 406, V1 and 404 of the system 400. The refrigeration system 452 is a closed-loop refrigeration system that supplies deeply subcooled liquid to the ESC 402. The refrigeration system 452 ensures that only liquid and no vapor phase is delivered to the ESC 402, which can reduce challenges in managing two-phase flow. In some applications, the system 450 can be used as an alternative to the phase separating design shown in FIG. 16. The valve V2 is optional and can be used to regulate the pressure of the boiling fluid in the evaporative cooling system in the ESC 402.

FIG. 18 shows a method 500 for controlling the cooling systems described above. For example, the method can be performed by the controller 410 of FIGS. 17A and 17B. At 502, the method 500 monitors the liquid level in the cooling system. At 504, the method 500 determines if the liquid level in the cooling system is less than or equal to a first set point. If the liquid level in the cooling system is not less than or equal to the first set point, the method 500 continues to the monitor the liquid level in the cooling system at 502. If the liquid level in the cooling system is less than or equal to the first set point, the method 500 supplies fluid to the cooling system at 506. At 508, the method 500 determines if the liquid level in the cooling system is greater than or equal to a second set point. If the liquid level in the cooling system is not greater than or equal to the first set point, the method 500 continues to supply the liquid the cooling system at 506 until the liquid level in the cooling system greater than or equal to the second set point. If the liquid level in the cooling system is greater than or equal to the first set point, the method 500 returns to 502.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A baseplate of a substrate support assembly comprising:
a cavity between an upper region, a lower region, and sidewalls of the baseplate;
a plurality of pillars arranged in the cavity between the upper and lower regions;
an inlet to supply a liquid to the cavity; and
an outlet to vent vapor of the liquid.

2. The baseplate of claim 1 wherein the pillars are coated with a wicking material.

3. The baseplate of claim 1 wherein the cavity is cylindrical and a height of the cavity is less than a diameter of the cavity.

4. The baseplate of claim 1 wherein the pillars are cylindrical and extend from a bottom of the cavity to a top of the cavity.

5. The baseplate of claim 1 wherein the pillars are cylindrical and extend vertically from a bottom of the cavity to a top of the cavity.

6. The baseplate of claim 1 wherein the baseplate and the cavity are cylindrical and wherein the cavity extends radially along a diameter of the baseplate.

7. The baseplate of claim 1 wherein the inlet is smaller in size than the outlet.

8. The baseplate of claim 1 wherein the inlet is adjacent to a bottom of the cavity and wherein the outlet is adjacent to a top of the cavity.

9. The baseplate of claim 1 further comprising:
a channel arranged in the baseplate above the cavity, wherein the outlet is connected to a first end of the channel; and
a second end of the channel is connected to a vent in the baseplate.

10. The baseplate of claim 9 wherein:
the baseplate and the cavity are cylindrical;
the channel is spiral shaped; and
the cavity and the channel extend radially along a diameter of the baseplate.

11. The baseplate of claim 9 wherein:
the baseplate and the cavity are cylindrical;
the channel is bifilar; and
the cavity and the channel extend radially along a diameter of the baseplate.

12. The baseplate of claim 1 further comprising:
a second cavity between the cavity and the lower region of the baseplate;
wherein the outlet is connected to the second cavity; and
wherein the second cavity is connected to a vent in the baseplate.

13. The baseplate of claim 1 further comprising:
a channel arranged in the baseplate above the cavity; and
a second cavity between the cavity and the lower region of the baseplate;
wherein the outlet is connected to a first end of the channel and to the second cavity; and
wherein the second cavity and a second end of the channel are connected to respective vents in the baseplate.

14. The baseplate of claim 13 wherein the channel is bifilar or spiral shaped.

15. The baseplate of claim 13 wherein the baseplate is cylindrical and wherein the cavity, the channel, and the second cavity extend radially across a diameter of the baseplate.

16. A baseplate of a substrate support assembly comprising:
a first channel arranged in the baseplate;
a second channel arranged above the first channel;
a plurality of vertical channels connecting the first channel to the second channel;
an inlet to supply a liquid to the first channel; and
an outlet to vent vapor of the liquid from the second channel.

17. The baseplate of claim 16 wherein the second channel has a larger cross-section than the first channel.

18. The baseplate of claim 16 wherein inner walls of the second channel are coated with a wicking material.

19. The baseplate of claim 16 wherein the first and second channels are spiral shaped.

20. The baseplate of claim 16 wherein the first and second channels are bifilar.

21. The baseplate of claim 16 wherein the first and second channels are parallel to each other.

22. The baseplate of claim 16 wherein the baseplate is cylindrical and wherein the first and second channels extend radially across a diameter of the baseplate.

23. The baseplate of claim 16 wherein:
the inlet is connected to a first end of the first channel;
a second end of the first channel is terminated;
a first end of the second channel is terminated; and
a second end of the second channel is connected to the outlet.

24. The baseplate of claim 16 wherein:
the inlet is connected to a first end of the first channel;
a second end of the first channel is terminated; and
the baseplate further comprises:
a third channel arranged above the second channel;
a first end of the second channel is connected to a first end of the third channel;
a second end of second channel is terminated; and
a second end of the third channel is connected to the outlet.

25. The baseplate of claim 24 wherein the second channel has a larger cross-section than the first channel and wherein the third channel has a larger cross-section than the second channel.

26. The baseplate of claim 24 wherein the third channel is bifilar or spiral shaped and is parallel to the first and second channels.

27. The baseplate of claim 24 wherein the first, second, and third channels are spiral shaped and wherein the third channel spirals in an opposite direction relative to the first and second channels.

28. The baseplate of claim 24 wherein the baseplate is cylindrical and wherein the first, second, and third channels extend radially across a diameter of the baseplate.

29. The baseplate of claim 16 wherein:
the inlet is connected to a first end of the first channel;
a second end of the first channel is terminated;
the baseplate further comprises:
a cavity between the first channel and a bottom region of the baseplate;
a first end of the second channel is connected to the cavity;
a second end of second channel is terminated; and
the cavity is connected to the outlet.

30. The baseplate of claim 29 wherein the baseplate is cylindrical and wherein the first and second channels and the cavity extend radially across a diameter of the baseplate.

31. The baseplate of claim 29 further comprising a plurality of porous plugs, each of the porous plugs having a first end connected to the first channel and a second end connected to a passage connecting the first end of the second channel to the cavity.

32. The baseplate of claim 31 wherein the vertical channels connecting the first channel to the second channel extend below the first ends of the porous plugs towards a center of the first channel.

33. The baseplate of claim 16 wherein:
the inlet is connected to a first end of the first channel;
a second end of the first channel is terminated; and
the baseplate further comprises:
a third channel arranged above the second channel;
a cavity between the first channel and a bottom region of the baseplate;
a first end of the second channel is connected to a first end of the third channel and to the cavity;
a second end of second channel is terminated; and
a second end of the third channel and the cavity are connected to respective vents in the baseplate.

34. The baseplate of claim 33 wherein the second channel has a larger cross-section than the first channel and wherein the third channel has a larger cross-section than the second channel.

35. The baseplate of claim 33 wherein the third channel is bifilar or spiral shaped and is parallel to the first and second channels.

36. The baseplate of claim 33 wherein the first, second, and third channels are spiral shaped and wherein the third channel spirals in an opposite direction relative to the first and second channels.

37. The baseplate of claim 33 wherein the baseplate is cylindrical and wherein the first, second, and third channels and the cavity extend radially across a diameter of the baseplate.

38. The baseplate of claim 16 further comprising:
a refrigeration system configured to supply the liquid to the inlet based on feedback from the outlet;
a level sensor disposed in the first channel to sense a level of the liquid in the first channel; and
a controller configured to control supply of the liquid from the refrigeration system to the inlet based on the level of the liquid in the evaporative cooling system.

39. A substrate processing system comprising:
a substrate support assembly;
an evaporative cooling system disposed in the substrate support assembly;
a liquid supply configured to provide liquid to the evaporative cooling system;
a level sensor disposed in the evaporative cooling system to sense a level of the liquid in the evaporative cooling system; and
a controller configured to control supply of the liquid from the liquid supply to the evaporative cooling system based on the level of the liquid in the evaporative cooling system.

40. The substrate processing system of claim 39 further comprising:
a gas supply to provide a pressurized gas to the liquid supply; and
a pressure sensor to sense a system pressure in the substrate support assembly;
wherein the controller is configured to:
control supply of the pressurized gas from the gas supply to the liquid supply based on the system pressure; and
control a pressure at which the liquid evaporates based on the controlled supply of the pressurized gas from the gas supply to the liquid supply.

41. The substrate processing system of claim 39 wherein the evaporative cooling system comprises:
a cavity between an upper region, a lower region, and sidewalls of the substrate support assembly;
a plurality of pillars arranged in the cavity between the upper and lower regions, wherein the pillars are coated with a wicking material;
an inlet to supply the liquid from the liquid supply to the cavity; and
an outlet to vent vapor of the liquid.

42. The substrate processing system of claim 41 wherein the evaporative cooling system comprises:
a channel arranged in the substrate support assembly above the cavity, wherein the outlet is connected to the channel; and
wherein the channel is connected to a vent in the substrate support assembly.

43. The substrate processing system of claim 41 wherein the evaporative cooling system comprises:
a second cavity in the substrate support assembly between the cavity and the lower region of the substrate support assembly;
wherein the outlet is connected to the second cavity; and
wherein the second cavity is connected to a vent in the substrate support assembly.

44. The substrate processing system of claim 41 wherein the evaporative cooling system comprises:
a channel arranged in the substrate support assembly above the cavity; and
a second cavity in the substrate support assembly between the cavity and the lower region of the substrate support assembly;
wherein the outlet is connected to the channel and to the second cavity; and
wherein the second cavity and the channel are connected to respective vents in the substrate support assembly.

45. The substrate processing system of claim 39 wherein the evaporative cooling system comprises:
a first channel arranged in the substrate support assembly;
a second channel arranged in the substrate support assembly above the first channel;
a plurality of vertical channels arranged in the substrate support assembly to connect the first channel to the second channel;
an inlet to supply the liquid from the liquid supply to the first channel; and
an outlet to vent vapor of the liquid from the second channel.

46. The substrate processing system of claim 45 wherein the evaporative cooling system comprises:
a third channel arranged in the substrate support assembly above the second channel;
wherein the third channel is connected to the second channel and to the outlet;
wherein the second channel has a larger cross-section than the first channel; and
wherein the third channel has a larger cross-section than the second channel.

47. The substrate processing system of claim 45 wherein the evaporative cooling system comprises:
a cavity in the substrate support assembly between the first channel and a bottom region of the substrate support assembly;
wherein the second channel is connected to the cavity; and
the cavity is connected to the outlet.

48. The substrate processing system of claim 45 wherein the evaporative cooling system comprises:
a third channel arranged in the substrate support assembly above the second channel; and
a cavity in the substrate support assembly between the first channel and a bottom region of the substrate support assembly;
wherein the second channel is connected to the third channel and to the cavity; and
wherein the third channel and the cavity are connected to respective vents in the substrate support assembly.
